(19) United States
(12) Patent Application Publication
(10) Pub. No.: US 2025/0212438 A1
(43) Pub. Date: Jun. 26, 2025

(54) SELF-ALIGNED HIGH ELECTRON MOBILITY TRANSISTOR (HEMT) AND MANUFACTURING METHOD THEREOF

(71) Applicant: RFHIC Corporation, Gwacheon-si (KR)

(72) Inventors: Ji Hun UM, Daejeon (KR); Young Jin KIM, Seoul (KR); June Sik KWAK, Cheonan (KR)

(21) Appl. No.: 18/977,319

(22) Filed: Dec. 11, 2024

(30) Foreign Application Priority Data
Dec. 22, 2023 (KR) 10-2023-0190155

(51) Int. Cl. H10D 30/01; H10D 30/47; H10D 64/00; H10D 64/23

(52) U.S. Cl. CPC H10D 30/015; H10D 30/475; H10D 64/111; H10D 64/251

(57) ABSTRACT

The present disclosure aims to provide a self-aligned high electron mobility transistor (HEMT) and a manufacturing method thereof, in which source and drain electrodes and a source field plate are formed in the same process. A source field plate is used to define the position of the gate electrode, thereby simplifying the process steps and preventing performance degradation due to alignment errors among the electrodes.

### STATEMENT REGARDING KOREAN GOVERNMENT SUPPORT

This invention was made with support under Project Unique Number 9991008828 and Project Number 22-CM-TN-15, funded by the Ministry of Trade, Industry, and Energy and the Defense Acquisition Program Administration of the Republic of Korea. The project, titled ‘Development of GaN-based 150 nm Process Technology and Application System (3.5 km Drone Detection Radar),’ was managed by the Institute of Civil-Military Technology Cooperation (ICMTC) under the Civil-Military Technology Cooperation Program. The project was conducted by RFHIC Corporation from Jan. 1, 2024, to Dec. 31, 2024

### CROSS-REFERENCE TO RELATED APPLICATION

This application is based on and claims priority under 35 U.S.C § 119(a) of a Korean patent application number 10-2023-0190155, filed on Dec. 22, 2023, in the Korean Intellectual Property Office, the disclosure of which is incorporated by reference herein in its entirety.

### BACKGROUND

### Technical Field

The present disclosure relates to a self-aligned high electron mobility transistor and a method for manufacturing the same, and more specifically, to a self-aligned high electron mobility transistor that enables precise alignment of electrodes of the transistor and a method for manufacturing the same.

### Description of Related Technology

III-V group compound semiconductor transistors are increasingly utilized due to the development of ultra-high frequency band wireless communication technologies, such as 5G and satellite communications, and the performance limitations of conventional silicon-based transistors, such as switching and pressure resistance characteristics.

III-V compound semiconductors leverage the piezoelectric effect arising from the junction of heterogeneous materials and the resulting formation of a two-dimensional electron gas (2DEG). By forming a high electron mobility transistor (HEMT), these semiconductors achieve high electron mobility, enabling high-speed switching and high breakdown voltage characteristics. These features make the semiconductors well-suited for application in ultra-high frequency wireless communication, gaining significant attention from the industry.

In the process of forming an HEMT, a gate electrode is formed between the source and drain electrodes to control the movement of electrons flowing through the source and drain electrodes, and a source field plate is formed to disperses the electric field concentrated beneath the gate electrode, thereby improving breakdown voltage and reducing leakage current during transistor operation.

Previously, the source and drain electrodes, gate electrode, and source field plate are formed through separate exposure and deposition processes. As a result, even when the source and drain electrodes, gate electrode, and source field plate are formed on the same substrate, alignment errors occurring in these processes leads to reduced device yield and performance uniformity.

In particular, the gate electrode must be formed at the exact position between the source electrode and the drain electrode. A length of an area in contact with a channel layer must be formed uniformly, and a spacing between the gate electrode and the source and drain electrodes must also be uniform. However, in a conventional manufacturing process, the source, drain, and gate electrodes are formed through separate exposure and deposition processes. This results in misalignment of the electrodes, leading to a decrease in the performance uniformity of the device.

In addition, the source field plate must also be formed at an accurate position on the gate electrode, but since the gate electrode and the source field plate are formed through different exposure and deposition processes, it is difficult to form them at an accurate position due to misalignment, and there is a problem that the performance uniformity of the device deteriorates due to different electric field dispersion effects.

Recent publications, such as Korean Patent Application Publication No. 2022-0006402 (Title: High Electron Mobility Transistor, Publication Date: Jul. 8, 2022) and Japanese Patent Registration No. 7127693 (Title: Field Effect Transistor, Publication Date: Aug. 30, 2022), reveal that the formation processes for the source and drain electrodes, gate electrode, and source field plate are still performed independently. Consequently, the aforementioned issues arising from alignment errors occurring in the processes remain unresolved.

### SUMMARY

The present disclosure provides a self-aligned high electron mobility transistor (HEMT) and a manufacturing method thereof, in which source and drain electrodes and a source field plate are formed in the same process and a source field plate is used to define a position of the gate electrode, thereby simplifying the process steps and preventing performance degradation due to alignment errors among the electrodes.

The present disclosure also provides a self-aligned high electron mobility transistor (HEMT) and a manufacturing method thereof, in which a slanted etched surface is formed on a gate electrode so as not to form an edge where an electric field is concentrated, thereby enabling the electric field to be dispersed and improving breakdown voltage.

In one aspect, there is provided a self-aligned high electron mobility transistor (HEMT), and the HEMT includes: a substrate; a channel layer formed on the substrate; a barrier layer formed on the channel layer; a first insulating layer etched to a predetermined length on the barrier layer; source and drain electrodes formed on both sides of the first insulating layer on the barrier layer; a source field plate formed simultaneously with the source and drain electrodes on the first insulating layer; wherein the first insulating layer is etched using an etch-resistant pattern for protecting the first insulating layer, and wherein a reflow process is performed on the etch-resistant pattern so that an etched side of the first insulating layer in contact with the source field plate is slanted with respect to the source field plate, and a gate electrode is formed within the etched first insulating layer to contact the barrier layer.

The first insulating layer may be etched in multiple processes.

The first insulating layer may be etched in the reflow process at a temperature between 130 degrees and 170 degrees for 5 to 15 minutes.

The etch-resistant pattern may be formed of at least one of a photosensitive film, a metal layer, and an insulating layer.

The source field plate may be formed as a plurality of source plates with a regular interval on the first insulating layer, and the gate electrode is formed within an etched region of the first insulating layer based on the interval between the plurality of source plates.

The gate electrode may be formed within the etched region of the first insulating layer based on the entire gap between the plurality of source field plates.

The plurality of source field plates may serve as an etch-protective layer during an etching process of the first insulating layer.

The source and drain electrodes and the source field plate may be each formed as a laminated layer of one metallic element selected from a group of titanium (Ti), titanium nitride (TiN), aluminum (Al), nickel (Ni), gold (Au), tantalum (Ta), tantalum nitride (TaN), silicon (Si), and molybdenum (Mo), or as an alloy of two or more metallic elements from the group.

The source and drain electrodes may be formed of a metallic element identical to a metallic element of the source field plate.

One or more materials selected from a group of silicon nitride (SiN), silicon dioxide (SiO2), aluminum oxide (Al2O3), hafnium oxide (HfO2), and gallium oxide (Ga2O3) may be laminated in the first insulating layer.

In another aspect, there is provided a method for manufacturing a self-aligned high electron mobility transistor (HEMT), and the method incudes: preparing a substrate; forming a channel layer on the substrate; forming a barrier layer on the channel layer; etching a first insulating layer to a predetermined length on the barrier layer, using an etch-resistant pattern for protecting the first insulating layer; forming a source electrode and a drain electrode on both sides of the first insulating layer on the barrier layer, while simultaneously forming a source field plate on the first insulating layer; etching the first insulating layer based on the source field plate; and performing a reflow process on the etch-resistant pattern so that an etched surface of the first insulating layer in contact with the source field plate is slanted with respect to the source field plate, and forming a gate electrode within the etched first insulating layer to contact the barrier layer.

In etching the first insulating layer, the first insulating layer may be etched in multiple processes.

In etching the first insulating layer, the first insulating layer may be etched in the reflow process at a temperature between 130 degrees and 170 degrees for 5 to 15 minutes.

### BRIEF DESCRIPTION OF THE DRAWINGS

FIG. 1 illustrates a state in which a channel layer and a barrier layer are laminated on a substrate according to the present disclosure.

FIG. 2 illustrates a state in which the first insulating layer is deposited in FIG. 1.

FIG. 3 illustrates a state in which the first insulating layer is etched using an etch-resistant pattern formed of a photosensitive film, a metal layer, an insulating layer, or the like in FIG. 2.

FIG. 4 illustrates a state in which a first conductive layer is deposited using a pattern that facilitates the selective removal of a photosensitive film, a metal layer, an insulating layer, etc. in FIG. 3.

FIG. 5 illustrates a state in which a first conductive layer is deposited using a pattern that facilitates the selective removal of a photosensitive film, a metal layer, an insulating layer, or the like in FIG. 4.

FIG. 6 illustrates etching of a gate electrode region using the field plate and photosensitive film as etch masks in FIG. 5.

FIG. 7 illustrates a state in which a second conductive layer is deposited to form a gate electrode in FIG. 6.

FIG. 8 illustrates a state in which the second conductive layer is deposited in FIG. 7.

FIG. 9 illustrates a state in which the second conductive layer is etched using an etch-resistant pattern formed of a photosensitive film, a metal layer, an insulating layer, or the like in FIG. 8 to form a second insulating layer.

FIG. 10 illustrates a state in which a third conductive layer is deposited using a pattern that facilitates the selective removal of a photosensitive film, a metal layer, an insulating layer, or the like in FIG. 9.

### DETAILED DESCRIPTION

Hereinafter, embodiments of the disclosure will be described in detail with reference to the accompanying drawings, and the same or similar components are given the same reference numbers and redundant description thereof is omitted. In addition, in the following description of the embodiments, a detailed description of known functions and configurations incorporated herein will be omitted when it may impede the understanding of the embodiments.

While terms including ordinal numbers, such as “first” and “second,” etc., may be used to describe various components, such components are not limited by the above terms. The singular forms are intended to include the plural forms, unless the context clearly indicates a different meaning.

As used herein, the singular forms “a”, “an,” and “the” are intended to include the plural forms as well, unless the context clearly indicates otherwise.

It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Hereinafter, a self-aligned high electron mobility transistor (HEMT) and a manufacturing method thereof according to one embodiment of the present disclosure will be described in detail with reference to the accompanying drawings.

A high electron mobility transistor (HEMT), which is the subject of the present disclosure, is known as a heterojunction FET (HFET) or a modulation-doped FET (MODFET). The HEMT is a type of field effect transistor (FET) in which a hetero-junction is formed between a channel layer composed of a III-V group compound semiconductor element and a barrier layer having an electron affinity lower than that of the channel layer. The HEMT is able to operate at higher frequencies than ordinary transistors, reaching millimeter frequencies, and is used in high-frequency and high-power products, such as power amplifiers between mobile phone base stations and phased array lasers in military applications. For this reason, the HEMT is one of the most actively researched and developed semiconductor devices.

The present disclosure has been developed to prevent alignment errors between electrodes by newly defining a process for forming various electrodes on a channel layer and a barrier layer in manufacturing a HEMT, that is, a process for forming source and drain electrodes, a gate electrode, and a source field plate.

Previously, various electrodes were formed on a channel layer using separate processes. In other words, a source and drain electrode formation process, a gate electrode formation process, and a source field plate formation process were carried out independently of each other, but the alignment in the processes are not precise, resulting in positional misalignment between the electrodes, which led to poor performance uniformity of the HEMT.

In order to solve the positional misalignment between the electrodes, the present disclosure first forms source and drain electrodes and a source field plate by etching the source and drain electrodes and the source field plate on a channel layer and a barrier layer in a single process. Since the source and drain electrodes and the source field plate are formed in a single photo and patterning process and thus precisely aligned in position. In a subsequent process, a gate electrode is etched based on the position of the source field plate. As a result, the source, drain, and gate electrodes are also precisely aligned based on the position of the source field plate. Moreover, since the gate electrode is formed based on the position of the source field plate, the source field plate and the gate electrode are also precisely aligned in position.

Through this technical idea, the present disclosure solves the positional misalignment between electrodes (source and drain electrodes, gate electrode, and source field plate) of a HEMT, which has been a problem in the art. Hereinafter, a representative embodiment of the technical idea of the present disclosure will be described in more detail, in process sequence, with reference to the accompanying drawings.

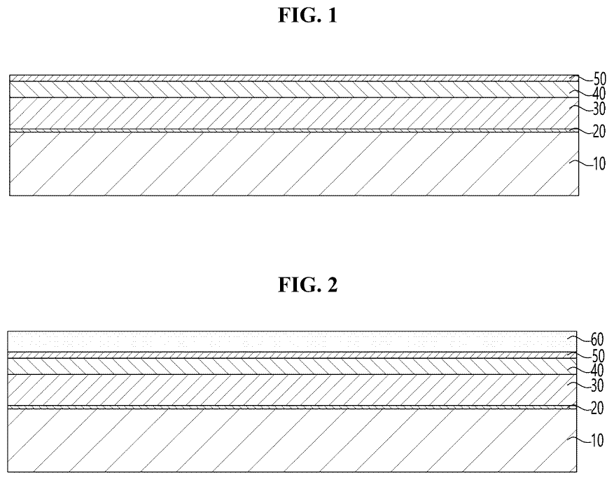

FIG. 1 illustrates a state in which a channel layer and a barrier layer are laminated on a substrate according to the present disclosure.

A compound semiconductor device including a high electron mobility transistor (HEMT) disclosed in the present disclosure, may have a seed layer 20, a buffer layer 30, a channel layer 40, and a barrier layer 50 sequentially laminated on a substrate 10. Each layer may be laminated using one or a combination of various epitaxial growth processes such as LPE, VPE, MOVPE, MOCVD, and MBE. Some layers may be omitted depending on the epitaxial processes.

The substrate 10 may be composed of an insulating material such as glass, sapphire, or quartz; a semiconductor material such as silicon, silicon carbide, indium-phosphide, silicon-germanium, gallium-arsenide, or gallium-nitride; or diamond, which has excellent heat dissipation properties. In addition, various materials suitable for laminating a semiconductor material may be used.

The seed layer 20 may serve as a growth nucleus for epitaxial growth of a semiconductor element on the substrate 10. The buffer layer 30 may reduce lattice mismatch of elements between the substrate 10 and the channel layer 40, which is a semiconductor element formed on the substrate 10. In addition, the buffer layer 30 may be composed of a material capable of trapping defects (e.g., dislocation), thereby suppressing defect diffusion. The seed layer 20 and buffer layer 30 may be composed of a compound of two materials including indium (In), gallium (Ga), aluminum (Al), nitrogen (N), etc.

The channel layer 40 may be a semiconductor element formed using an epitaxial growth technique, with a uniform composition free of impurity doping. The channel layer 40 may include a 2-dimensional electron gas (2DEG) region, which is a region where the movement of charges (electrons) between the channel layer 40 and the barrier layer 50 occurs in a HEMT.

In one embodiment, the channel layer 40 may be formed by combining III-V group compound semiconductor elements, and the number and shape thereof may vary. For instance, examples of binary compounds may include gallium-nitride (GaN), gallium-arsenide (GaAs), indium-phosphide (InP), aluminum-arsenide (AlAs), indium-arsenide (InAs), and indium-antimonide (InSb), and examples of ternary compounds include aluminum-gallium-nitride (AlGaN), indium-gallium-nitride (InGaN), aluminum-gallium-arsenide (AlGaAs), indium-gallium-arsenide (InGaAs), indium-gallium-phosphide (InGaP), indium-aluminum-phosphide (InAlP), and indium-aluminum-arsenide (InAlAs).

The barrier layer 50 has a larger band gap energy than that of the channel layer 40 and serves as a barrier to charge flow, enabling the formation of a 2DEG region where charges (electrons) move between the channel layer 40 and the barrier layer 50. In addition, the barrier layer 50 may form a Schottky junction (which is a junction between a semiconductor channel layer and a metal connected to the semiconductor channel layer) required to form a transistor with high operating speed between the gate electrode and the channel layer 40.

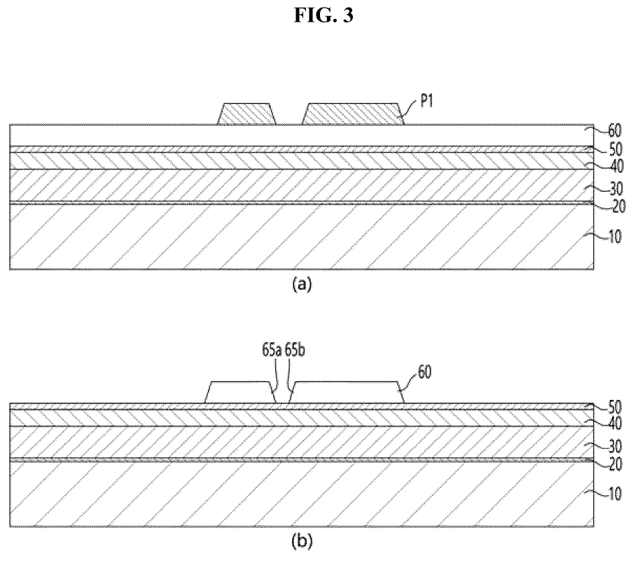

FIG. 2 illustrates a state in which a first insulating layer is deposited in FIG. 1, and FIG. 3 illustrates a state in which the first insulating layer is etched using an etch-resistant pattern formed of a photosensitive film, a metal layer, an insulating layer, or the like in FIG. 2.

Specifically, FIG. 2 illustrates a state in which a first insulating layer 60 is deposited on an upper side of the barrier layer 50 of FIG. 1. The first insulating layer 60 may be deposited using one or a combination of various deposition processes, including physical vapor deposition (PVD) methods such as sputtering, electron beam, thermal evaporation, etc., and chemical vapor deposition (CVD) methods such as LPCVD, MOCVD, PECVD, ALCVD, etc. In the first insulating layer 60, one or more materials selected from a group of silicon nitride (SiN), silicon dioxide (SiO2), aluminum oxide (Al2O3), hafnium oxide (HfO2), and gallium oxide (Ga2O3) are laminated. A source field plate is formed on an upper side of the first insulating layer 60 and serves as an etch-protective layer to define the position where the gate electrode is to be etched.

Meanwhile, FIG. 3 illustrates a state in which the first insulating layer 60 is etched using an etch-resistant pattern formed of a photosensitive film, a metal layer, an insulating layer, or the like.

Specifically, in this embodiment, the first insulating layer 60 is etched using a photosensitive film P1 as an etch-protective layer, as shown in (a) of FIG. 3. As a result, the first insulating layer 60, except for a region protected by the photosensitive film P1, is removed by etching, exposing the barrier layer 50 upward, as shown in (b) of FIG. 3. That is, as shown in FIG. 3, after the etching process of the first insulating layer is completed, the photosensitive film P1 is peeled off through a dry or wet etching or cleaning process, leaving only the first insulating layer 60 of a predetermined length.

The above etching process may include a reflow process. The reflow process is a process of bonding elements by applying heat, pressure, air, and the like to a chip. When the etching process including the reflow process is performed, an exposed surface of the first insulating layer 60, which is exposed to the outside, may form a slanted shape, similar to etched surfaces 65a and 65b.

The etching process may be performed multiple times. If the first insulating layer 60 is formed in a single etching process, the etching process is performed using high energy. In this case, each edge of the etched surfaces of the first insulating layer 60 may be formed into a nearly vertical right-angle shape. If each edge of the etched surfaces of the first insulating layer 60 is formed in a right-angle shape, the electric field concentrates in the edge, leading to a low breakdown voltage.

To address this issue, the etching process may be performed with low plasma energy. However, if the etching process is performed in this manner, the energy linearity for etching the surfaces of the first insulating layer 60 is reduced, increasing isotropy and resulting in a jar-shaped profile.

To this end, the etching process is repeated multiple times to form the edges of the etched surface 65a and 65b of the first insulating layer 60 to be slanted. For example, the reflow process is performed at a temperature of 130 to 170 degrees for approximately 5 to 15 minutes. In particular, in a first etching process, only a part of the first insulating layer 60 is etched under a plasma condition with high energy linearity to form the slanted etched surfaces 65a and 65b. Next, in a second etching process, the first insulating layer 60 is etched under a plasma condition with lower energy than that of the first etching process to minimize damage to the channel layer 40. In addition, as the second etching condition uses relatively lower energy plasma compared to the first etching condition, a smaller region is etched than in the first etching process. This naturally results in the slanted etched surfaces 65a and 65b.

As such, by etching the first insulating layer 60 to form the slanted etched surfaces 65a and 65b, the formation of edges where the electric field would concentrate may be avoided, thereby dispersing the electric field and improving the breakdown voltage.

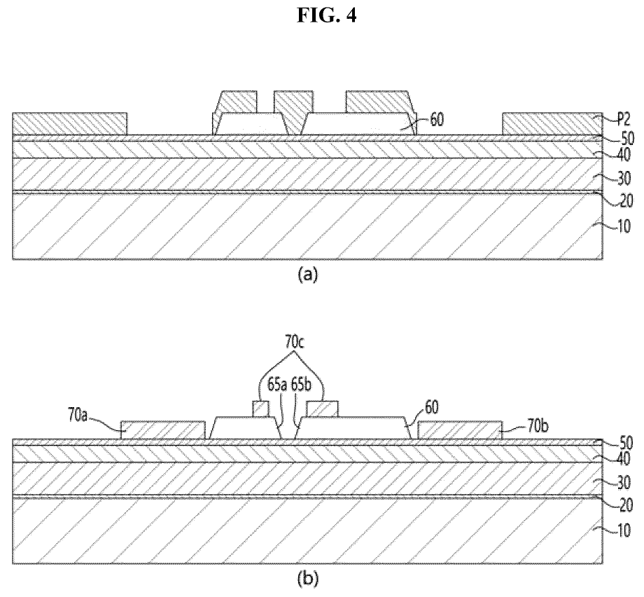

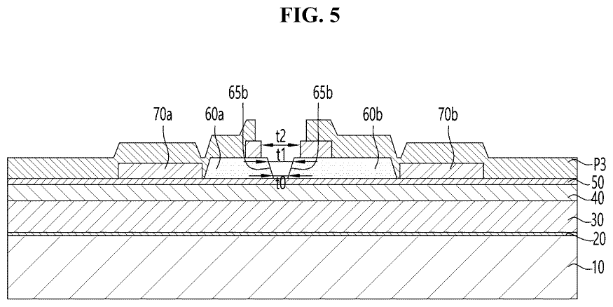

Meanwhile, FIG. 4 illustrates a state in which a first conductive layer is deposited using a pattern that facilitates the selective removal of a photosensitive film, a metal layer, an insulating layer, or the like, as shown in FIG. 3.

The process illustrated in FIG. 4 is one of the main processes of the present disclosure, and demonstrates the simultaneous formation of source and drain electrodes and a source field plate through a single patterning process.

As shown in (a) of FIG. 4, a photosensitive film P2 is formed with a predetermined thickness on a barrier layer 50 and a first insulating layer 60 in a patterning process, which is performed on an upper side of the first insulating layer 60 of FIG. 3 using a pattern that facilitates the selective removal of the photosensitive film P2. As a result, the positions of the source and drain electrodes, as well as the position of the source field plate, may be patterned through exposure and development. Thereafter, as shown in (b) of FIG. 4, patterning may be performed so that the source and drain electrodes are positioned on both sides of the first insulating layer 60, while the source field plate is positioned on the upper side of the first insulating layer 60.

The first conductive layer 70 to be patterned may be deposited with a predetermined thickness. That is, the first conductive layer 70 is deposited with a predetermined thickness not only on the upper side of the photosensitive film P2 but also on the exposed upper side of the exposed barrier layer 50 and the upper side of the first insulating layer 60. The first conductive layer 70 may be deposited using one or a combination of various deposition processes, including physical vapor deposition (PVD) methods such as sputtering, electron beam, thermal evaporation, etc., and chemical vapor deposition (CVD) methods such as LPCVD, MOCVD, PECVD, ALCVD, etc. This first conductive layer 70 may be formed as a laminated layer or alloy of one or more materials selected from among titanium (Ti), titanium nitride (TiN), aluminum (Al), nickel (Ni), gold (Au), tantalum (Ta), tantalum nitride (TaN), silicon (Si), or molybdenum (Mo). According to the present disclosure, the first conductive layer 70 may be formed of a single metallic element because the deposition of the first conductive layer 70 is performed in a single process.

Referring again to the drawing, the unpatterned first conductive layer 70 and the photosensitive film P2 may be peeled off in a dry or wet etching or cleaning process. As a result, source and drain electrodes 70a and 70b may be formed on both sides of the first insulating layer 60, and a source field plate 70c may be formed on the upper side of the first insulating layer 60. As described above, since the source and drain electrodes 70a and 70b and the source field plate 70c are simultaneously formed in a single patterning process, the source and drain electrodes 70a and 70b and the source field plate 70c are precisely aligned in position through precise patterning. Accordingly, since the source and drain electrodes 70a and 70b and the source field plate 70c are formed in independent and separate processes, the misalignment caused by alignment errors during the processes may be resolved.

Meanwhile, during the etching process of the first insulating layer 60, a first first insulating layer 60a may be formed at the center of the first insulating layer 60 and a second first insulating layer 60b spaced apart from the first first insulating layer 60a may be formed. At this point, the source field plate 70c is formed on each of the first first insulating layer 60a and the second first insulating layer 60b.

In one embodiment of the present disclosure, the etched surfaces 65a and 65b of the first insulating layer 60 are formed to be slanted. Specifically, the etched surface 65a of the first first insulating layer 60a is slanted toward the second first insulating layer 60b, and the etched surface 65a of the second first insulating layer 60b is slanted toward the first first insulating layer 60a. In particular, as illustrated in FIG. 5, a width of the first first insulating layer 60a formed on the first insulating layer 60 may be wider than a lower interval t0 toward the barrier layer 50.

As a result, a second interval t2 between the source field plate 70c formed on the first first insulating layer 60a and the source field plates 70c formed on the second first insulating layer 60b is larger than the width of the first first insulating layer 60a.

FIGS. 5 to 8 illustrate another main process of the present disclosure, which is a process of etching a gate electrode based on the source field plate 70c formed in a previous process.

Since the source field plate 70c and the source and drain electrodes 70a and 70b are simultaneously formed in a single process and aligned in position, forming the gate electrode based on the source field plate 70c ensures precise alignment between the gate electrode and the source and drain electrodes 70a and 70b. The present disclosure addresses technical issues, such as performance uniformity deterioration caused by alignment errors, by precisely aligning the positions of the source and drain electrodes, gate electrode, and source field plate included in an electrode structure of a high electron mobility transistor (HEMT).

FIG. 5 illustrates a state in which a photosensitive film P3 for forming a gate electrode on the source and drain electrodes 70a and 70b and the source field plate 70c, which are shown in FIG. 4, is formed and patterned. That is, through a patterning process, the photosensitive film P3 is formed with a predetermined thickness on the upper sides of the barrier layer 50, first insulating layer 60, source and drain electrodes 70a and 70b, and source field plate 70c, and the position where the gate electrode is to be formed is patterned in the patterning process.

At this point, the position where the gate electrode is to be formed is patterned based on the source field plate 70c. In one embodiment of the present disclosure, a plurality of source field plates 70c are formed on the first insulating layer 60 at a regular interval, and the gate electrode is patterned based on the interval between the source field plates 70c. That is, in the photosensitive film P3, a patterning width of the photosensitive film P3 to form the gate electrode may be defined to be larger, equal to, or smaller than the interval between the plurality of source field plates 70c. Additionally, the patterning is performed so that the gate electrode has a predetermined width based on one side of the interval between the plurality of source field plates 70c.

Preferably, the patterning is performed so that the gate electrode is etched over the entire interval t2 between the plurality of source field plates 70c. Although, in this embodiment, the patterning process using the photosensitive film P3 is illustrated, aspects of the present disclosure are not limited thereto and instead patterning may be performed using one or more photosensitive films P3. At this point, it is not easy in an actual process to achieve a pattern width that is completely identical to an interval width between the plurality of source field plates 70c. According to the present disclosure, as shown in FIG. 5, a patterning width t2 of the photosensitive film P3 may be formed to be wider than the interval t1 between the plurality of source field plates 70c. In this way, by making the patterning width t2 of the photosensitive film P3 larger than the interval t1 between the plurality of source field plates 70c, process tolerance may be allowed in the patterning process, thereby improving workability and increasing the device yield.

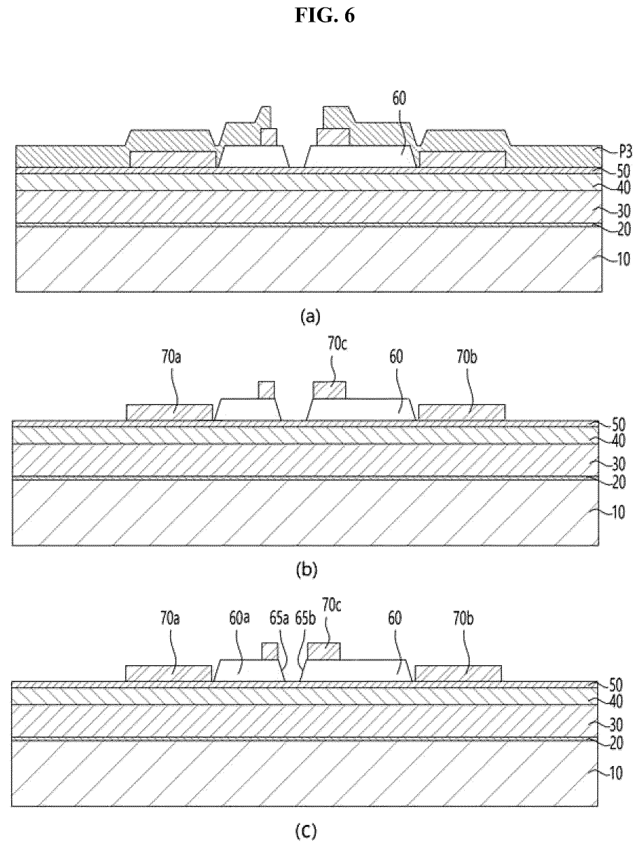

Then, the photosensitive film P3 is etched, as shown in (b) and (c) of FIG. 6. In the embodiment of the present disclosure, the source field plates 70c are formed on the first insulating layers 60 where the first first insulating layer 60a is formed between the slanted etched surfaces 65a and 65b, and each source field plate 70c has a width equal to the first first insulating layer 60a, which corresponds to an upper interval of the first insulating layer 60. This is because the plurality of source field plates 70c serve as etch-protective layers.

According to the present disclosure, by forming the plurality of source field plates 70c and positioning the gate electrode within an interval between the plurality of source field plates 70c, the plurality of source field plates 70c serve as an etch-protective layer during a process of etching the gate electrode. Accordingly, the plurality of source field plates 70c enables precise control of both the position and width of the gate electrode. As a result, the gate electrode and the source and drain electrodes 70a and 70b may be further precisely aligned in position.

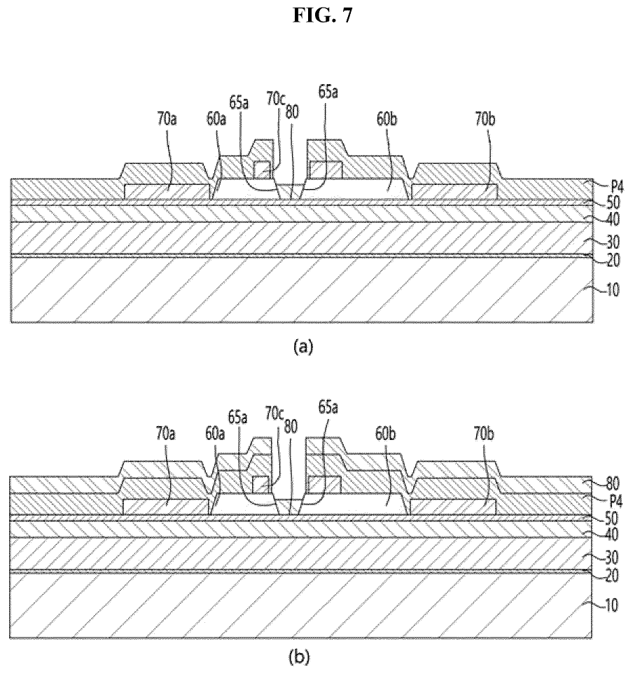

Referring to FIG. 7, FIG. 7 illustrates a state in which a second conductive layer 80 is deposited with a predetermined thickness on an upper side of a photosensitive film P4 to form a gate electrode. The second conductive layer 80 is deposited with the predetermined thickness not only on the upper side of the photosensitive film P4 but also on an etched side of the first insulating layer 60, which is etched over an interval between a plurality of source field plates 70c. The second conductive layer 80 may be deposited using one or a combination of various deposition processes, including physical vapor deposition (PVD) methods such as sputtering, electron beam, thermal evaporation, etc., and chemical vapor deposition (CVD) methods such as LPCVD, MOCVD, PECVD, ALCVD, etc. This second conductive layer 80 may be formed as a laminated layer or alloy of one or more materials selected from among nickel (Ni), gold (Au), tungsten (W), and tungsten carbide (WC). According to the present disclosure, the second conductive layer 80 may be formed of the same metallic element as a metallic element used in the deposition process of the source and drain electrodes and the source field plate.

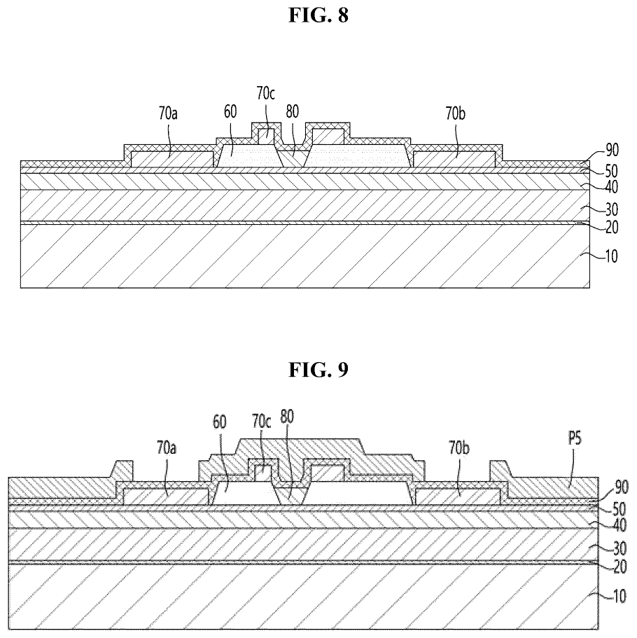

FIG. 8 illustrates a state in which the second conductive layer 80 and the photosensitive film P4, which have not been patterned in an etching and peeling process, are peeled off in a dry or wet etching or cleaning process. The second conductive layer 80 remains only within an interval between the plurality of source field plates 70c, and this remaining second conductive layer 80 serves as a gate electrode. As described above, because the source and drain electrodes 70a and 70b and the source field plates 70c are simultaneously formed in a single patterning process and thus precisely aligned in position, the gate electrode formed within the interval between the plurality of source field plates 70c is also precisely aligned based on the source and drain electrodes 70a and 70b. This overcomes the electrode positional misalignment caused by alignment errors occurring when the gate electrode, the source and drain electrodes, and the source field plates are individually formed in separate processes.

Specifically, as illustrated in FIG. 9, a second insulating layer 90 may be deposited with a predetermined thickness on a gate electrode 80. The second insulating layer 90 is deposited with the predetermined thickness on upper sides of the barrier layer 50, the first insulating layer 60, the source and drain electrodes 70a and 70b, the source field plate 70c, and the gate electrode 80 in a deposition process, and the second insulating layer 90 serves as a protective layer for the aforementioned components. The second insulating layer 90 may be deposited using one or a combination of various deposition processes, including physical vapor deposition (PVD) methods such as sputtering, electron beam, thermal evaporation, etc., and chemical vapor deposition (CVD) methods such as LPCVD, MOCVD, PECVD, ALCVD, etc. In the second insulating layer 90, one or more materials selected from a group of silicon nitride (SiN), silicon dioxide (SiO2), aluminum oxide (Al2O3), hafnium dioxide (HfO2), and gallium oxide (Ga2O3) may be laminated.

Next, a photosensitive film P5 is formed with a predetermined thickness on the upper side of the second insulating layer 90, the positions of the source and drain electrodes 70a and 70b are patterned in the photosensitive film P5 in a patterning process, and the second insulating layer 90 is etched using the pattern of the photosensitive film P5. An etching process is performed on the second insulating layer 90 using the photosensitive film P5 as an etch-protective layer. As a result, the unprotected region of the second insulating layer 90, except for a region protected by the photosensitive film P5, is removed by etching, exposing the source and drain electrodes 70a and 70b. After the etching process, the photosensitive film P5 is peeled off in a dry or wet etching or cleaning process, leaving the second insulating layer 90 as a protective layer for the uppermost layers, except for the upper sides of the source and drain electrodes 70a and 70b.

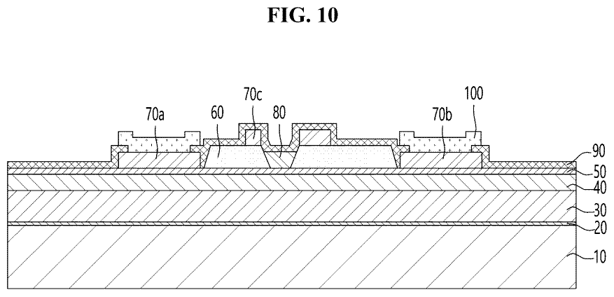

Meanwhile, FIG. 10 illustrates a process of forming a third conductive layer 100 on the exposed upper sides of the source and drain electrodes 70a and 70b, which are exposed in the previous process.

As shown in FIG. 10, the third conductive layer 100 is formed with a predetermined thickness on the exposed upper sides of the source and drain electrodes 70a and 70b, and the upper sides of the source and drain electrodes 70a and 70b are patterned through a patterning process. The third conductive layer 100 is deposited with the predetermined thickness to form a source through-hole electrode and a drain through-hole electrode. The third conductive layer 100 is deposited with the predetermined thickness on the exposed upper sides of the source and drain electrodes 70a and 70b. The third conductive layer 100 may be deposited using one or a combination of various deposition processes, including physical vapor deposition (PVD) methods such as sputtering, electron beam, thermal evaporation, etc., and chemical vapor deposition (CVD) methods such as LPCVD, MOCVD, PECVD, ALCVD, etc. The third conductive layer 100 may be formed as a laminated layer or alloy of one or more materials selected from among titanium (Ti), titanium nitride (TiN), aluminum (Al), nickel (Ni), gold (Au), tantalum (Ta), tantalum nitride (TaN), silicon (Si), and molybdenum (Mo). According to the present disclosure, the third conductive layer 100 may be formed of the same metallic element as a metallic element used in the deposition process of the source and drain electrodes, the source field plate, and the gate electrode.

Thereafter, the third conductive layer 100 that has not been patterned in an etching and peeling process may be peeled off in a dry or wet etching or cleaning process. The final third conductive layer 100 forms a source through-hole electrode electrically connected to the upper side of the source electrode 70a and a drain through-hole electrode electrically connected to the upper side of the drain electrode 70b.

In the self-aligned HEMT and the manufacturing method thereof according to the present disclosure, etching and deposition of source and drain electrodes and a source field plate are performed in a single process and a gate electrode is formed based on the source field plate, thereby preventing device alignment errors caused by alignment errors during different processes.

As a result, alignment errors between the gate electrode and the source and drain electrodes, as well as between the gate electrode and the source field plate, are prevented, improving device yield and performance uniformity. As a result, alignment errors between the gate electrode and the source and drain electrodes, as well as between the gate electrode and the source field plate, are prevented, improving device yield and performance uniformity.

In addition, by etching the gate electrode, which is in contact with the barrier layer, at an angle, the edge shape toward the drain electrode is eliminated, thereby preventing electric field concentration and enhancing breakdown voltage.

The technical features disclosed in each embodiment of the present disclosure are not limited to a corresponding embodiment, and unless incompatible with each other, the technical features disclosed in each embodiment may be applied in combination to other embodiments.

Therefore, although each embodiment is described mainly about an individual technical feature, the technical features of the embodiments of the present disclosure may be applied in combination, unless incompatible with each other.

The present disclosure is not limited to the above-described embodiments and the accompanying drawings, and various modifications and changes may be made in view of a person skilled in the art to which the present disclosure pertains. Therefore, the scope of the present disclosure should be determined by the scope of the appended claims, and equivalents thereof.

What is claimed is:

1. A self-aligned high electron mobility transistor (HEMT) comprising:
a substrate;
a channel layer formed on the substrate;
a barrier layer formed on the channel layer;
a first insulating layer etched to a predetermined length on the barrier layer;
source and drain electrodes formed on both sides of the first insulating layer on the barrier layer;
a source field plate formed simultaneously with the source and drain electrodes on the first insulating layer;
wherein the first insulating layer is etched using an etch-resistant pattern for protecting the first insulating layer,
wherein a reflow process is performed on the etch-resistant pattern so that an etched side of the first insulating layer in contact with the source field plate is slanted with respect to the source field plate, and a gate electrode is formed within the etched first insulating layer to contact the barrier layer.

2. The self-aligned HEMT of claim 1, wherein the first insulating layer is etched in multiple processes.

3. The self-aligned HEMT of claim 1, wherein the first insulating layer is etched in the reflow process at a temperature between 130 degrees and 170 degrees for 5 to 15 minutes.

4. The self-aligned HEMT of claim 1, wherein the etch-resistant pattern is formed of at least one of a photosensitive film, a metal layer, and an insulating layer.

5. The self-aligned HEMT of claim 1, wherein the source field plate is formed as a plurality of source plates with a regular interval on the first insulating layer, and the gate electrode is formed within an etched region of the first insulating layer based on the interval between the plurality of source plates.

6. The self-aligned HEMT of claim 5, wherein the gate electrode is formed within the etched region of the first insulating layer based on the entire gap between the plurality of source field plates.

7. The self-aligned HEMT of claim 6, wherein the plurality of source field plates serve as a etch-protective layer during an etching process of the first insulating layer.

8. The self-aligned HEMT of claim 6,
wherein the source and drain electrodes and the source field plate are formed as a laminated layer of one metallic element selected from a group of titanium (Ti), titanium nitride (TiN), aluminum (Al), nickel (Ni), gold (Au), tantalum (Ta), tantalum nitride (TaN), silicon (Si), and molybdenum (Mo), or as an alloy of two or more metallic elements from the group.

9. The self-aligned HEMT of claim 8, wherein the source and drain electrodes are formed of a metallic element identical to a metallic element of the source field plate.

10. The self-aligned HEMT of claim 1, wherein one or more materials selected from a group of silicon nitride (SiN), silicon dioxide (SiO2), aluminum oxide (Al2O3), hafnium oxide (HfO2), and gallium oxide (Ga2O3) are laminated in the first insulating layer.

11. A method for manufacturing a self-aligned high electron mobility transistor (HEMT), the method comprising:
preparing a substrate;
forming a channel layer on the substrate;
forming a barrier layer on the channel layer;
etching a first insulating layer to a predetermined length on the barrier layer, using an etch-resistant pattern for protecting the first insulating layer;
forming a source electrode and a drain electrode on both sides of the first insulating layer on the barrier layer, while simultaneously forming a source field plate on the first insulating layer;
etching the first insulating layer based on the source field plate; and
performing a reflow process on the etch-resistant pattern so that an etched surface of the first insulating layer in contact with the source field plate is slanted with respect to the source field plate, and forming a gate electrode within the etched first insulating layer to contact the barrier layer.

12. The method of claim 11, wherein in etching the first insulating layer, the first insulating layer is etched in multiple processes.

13. The method of claim 11, wherein in etching the first insulating layer, the first insulating layer is etched in the reflow process at a temperature between 130 degrees and 170 degrees for 5 to 15 minutes.
